(19) United States
(12) Patent Application Publication
(10) Pub. No.: US 2013/0308283 A1
(43) Pub. Date: Nov. 21, 2013

(54) CONNECTOR, CIRCUIT MODULE, AND ELECTRONIC APPARATUS

(71) Applicant: KABUSHIKI KAISHA TOSHIBA, Tokyo (JP)

(72) Inventor: Ichioh Murakami, Inagi-shi (JP)

(73) Assignee: KABUSHIKI KAISHA TOSHIBA, Tokyo (JP)

(21) Appl. No.: 13/734,116

(22) Filed: Jan. 4, 2013

(30) Foreign Application Priority Data
May 16, 2012 (JP) 2012-112313

(51) Int. Cl. H01R 13/46; H05K 5/00; H05K 1/00

(52) U.S. Cl. CPC H01R 13/465; H05K 1/00; H05K 5/0069
USPC 361/752; 439/491; 361/748

(57) ABSTRACT

According to one embodiment, a connector includes a connector main body, and a mark. The connector main body is mounted on a connector mounting portion of a substrate, and has an outer surface extending along a direction intersecting with a mounting surface. The mark is provided on the outer surface of the connector main body. The mark configured to indicate a degree of tilt of the connector main body relative to the mounting surface.

### CROSS-REFERENCE TO RELATED APPLICATIONS

This application is based upon and claims the benefit of priority from Japanese Patent Application No. 2012-112313, filed May 16, 2012, the entire contents of which are incorporated herein by reference.

### FIELD

Embodiments described herein relate generally to a connector which is mounted on a void connector mounting portion provided in a substrate, and a circuit module which comprise the connector and an electronic apparatus.

### BACKGROUND

A connector such as an RGB connector or a USB connector is soldered to a substrate to be put into, for example, a void connector mounting portion which is cut out in a part of the substrate. Therefore, the overall connector cannot be supported by the substrate, and it is difficult to eliminate the tilt of the connector along the thickness direction of the substrate.

As a measure heretofore taken to cope with this problem, the degree of the tilt of the connector relative to the substrate is examined after the connector is soldered to the substrate. In this examination, a thickness gauge is inserted into a gap between one end of the connector and the substrate, and the dimensions of the gap are measured by the thickness gauge to check whether the degree of the tilt of the connector is within an allowable range.

However, the examination that uses the thickness gauge takes a lot of trouble with the measurement of the dimensions of the gap. Moreover, when other circuit components are disposed around the connector, it is difficult to insert the thickness gauge into the gap between one end of the connector and the substrate because of the circuit components blocking the way.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a portable computer according to a first embodiment;

FIG. 2 is an exemplary sectional view showing how an RGB connector is mounted on a printed wiring board according to the first embodiment;

FIG. 3 is an exemplary sectional view taken along line F3-F3 of FIG. 2;

FIG. 4 is an exemplary plan view showing how the RGB connector is mounted on the printed wiring board according to the first embodiment;

FIG. 5 is an exemplary sectional view showing a condition in which the degree of the tilt of the RGB connector relative to a mounting surface of the printed wiring board is within an allowable range;

FIG. 6 is an exemplary sectional view showing a condition in which the degree of the tilt of the RGB connector relative to the mounting surface of the printed wiring board is outside the allowable range;

FIG. 7 is an exemplary sectional view showing how an RGB connector is mounted on a printed wiring board according to a second embodiment; and

FIG. 8 is an exemplary sectional view showing how an RGB connector is mounted on a printed wiring board according to a third embodiment.

### DETAILED DESCRIPTION

Various embodiments will be described hereinafter with reference to the accompanying drawings. In general, according to one embodiment, a connector includes a connector main body, and a mark. The connector main body is mounted on a connector mounting portion of a substrate, and has an outer surface extending along a direction intersecting with a mounting surface. The mark is provided on the outer surface of the connector main body. The mark configured to indicate a degree of tilt of the connector main body relative to the mounting surface.

### First Embodiment

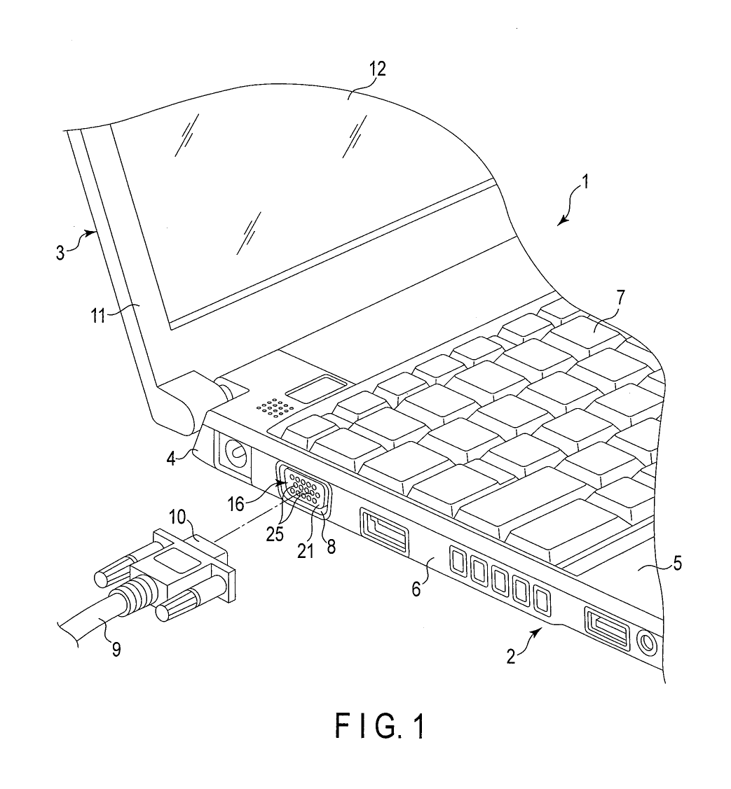

The first embodiment is described below with reference to FIG. 1 to FIG. 6.

FIG. 1 discloses a portable computer 1 which is an example of an electronic apparatus. The portable computer 1 comprises a main unit 2 and a display unit 3. The main unit 2 has a first housing 4. The first housing 4 is in a square box shape including an upper surface 5 and a side surface 6. A keyboard 7 is provided on the upper surface 5 of the first housing 4. A square opening 8 is provided in the side surface 6 of the first housing 4. The opening 8 is an element into which to put, for example, a plug 10 of an external display cable 9.

The display unit 3 comprises a second housing 11 and a liquid crystal display 12. The second housing 11 is pivotally coupled to the rear end of the first housing 4 via hinge fittings. The liquid crystal display 12 is housed in the second housing 11.

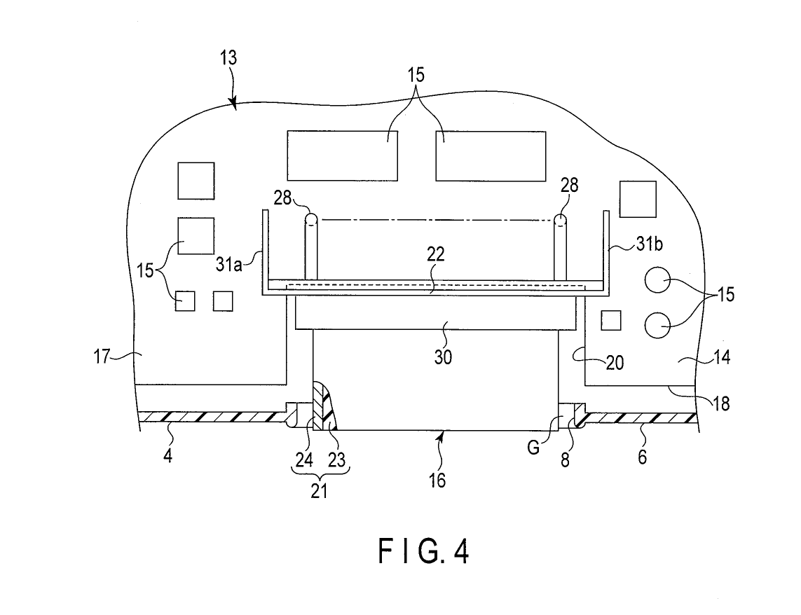

As shown in FIG. 4, a circuit module 13 is housed in the first housing 4. The circuit module 13 comprises a printed wiring board 14, circuit components 15 such as a semiconductor package and an IC chip, and an RGB connector 16.

The printed wiring board 14 is an example of a substrate, and is supported on the bottom of the first housing 4. The printed wiring board 14 has a flat mounting surface 17 and a side edge 18. The mounting surface 17 is located on the surface of the printed wiring board 14. The side edge 18 extends along the side surface 6 of the first housing 4.

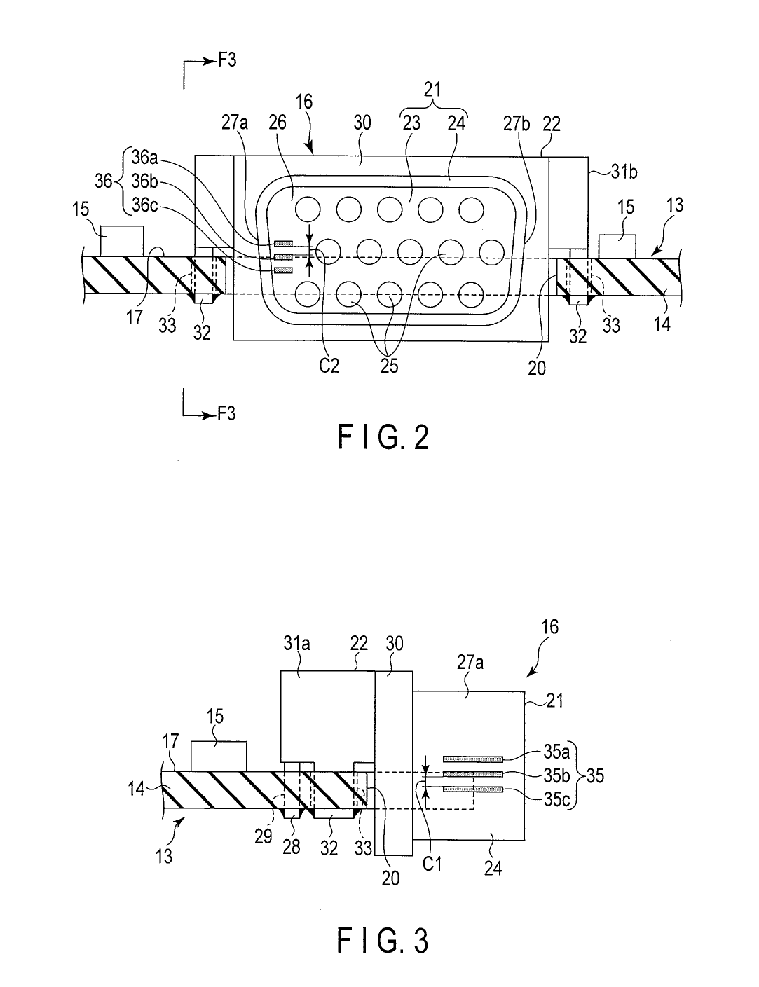

As shown in FIG. 2 to FIG. 4, a connector mounting portion 20 is formed in the printed wiring board 14. The connector mounting portion 20 is defined by a void region cut out in a part of the printed wiring board 14 to open in the side edge 18 of the printed wiring board 14. The connector mounting portion 20 passes through the printed wiring board 14 in its thickness direction at a position located off the mounting surface 17, and faces the opening 8 of the first housing 4.

The circuit components 15 are fixed to the mounting surface 17 of the printed wiring board 14 by such a means as reflow soldering. Some of the circuit components 15 are located around the connector mounting portion 20.

As shown in FIG. 2 to FIG. 4, the RGB connector 16 is mounted on the printed wiring board 14 to be located in the connector mounting portion 20. The RGB connector 16 is exposed to the outside of the portable computer 1 through the opening 8 of the first housing 4. The RGB connector 16 according to the first embodiment comprises a connector main body 21 and a connector holder 22.

The connector main body 21 is an element to which the plug 10 of the external display cable 9 is removably connected. The connector main body 21 has such a size as to be put into the connector mounting portion 20. The connector main body 21 includes a resin square insulating block 23 and a metal cover 24. The insulating block 23 has a black end face 26 in which a plurality of pinholes 25 are made. The end face 26 extends in a direction that intersects with the mounting surface 17 to erect on to the mounting surface 17 of the printed wiring board 14.

The cover 24 continuously surrounds an outer peripheral surface of the insulating block 23 except for the end face 26 of the insulating block 23. The cover 24 has a pair of side surfaces 27a and 27b. Side surfaces 27a and 27b have a silver color specific to metals, and face in a direction different from the end face 26 of the insulating block 23. Moreover, side surfaces 27a and 27b extend in a direction that intersects with the mounting surface 17 to erect on to the mounting surface 17 of the printed wiring board 14. Therefore, according to the first embodiment, the end face 26 of the insulating block 23 and side surfaces 27a and 27b of the cover 24 define the outer surface of the connector main body 21. The outer surface is exposed to the outside of the connector main body 21.

Furthermore, according to the first embodiment, the connector main body 21 has a plurality of lead terminals 28. The lead terminals 28 are projected to the rear of the insulating block 23 from the pinholes 25 of the insulating block 23, and then guided onto the mounting surface 17 of the printed wiring board 14. The tips of the lead terminals 28 are individually inserted in through-holes 29 made in the printed wiring board 14, and are soldered to the printed wiring board 14.

The connector holder 22 is an example of a support member which supports the connector main body 21. As shown in FIG. 2 to FIG. 4, the connector holder 22 includes a front panel 30 and a pair of side panels 31a and 31b. The front panel 30 is coupled to the connector main body 21 to be located in the rear of the connector main body 21. Side panel 31a extends from one end of the front panel 30 to the rear of the connector main body 21, and is thus located on the mounting surface 17 of the printed wiring board 14. Similarly, side panel 31b extends from the other end of the front panel 30 to the rear of the connector main body 21, and is thus located on the mounting surface 17 of the printed wiring board 14.

Each of side panels 31a and 31b has an engaging piece 32. The engaging pieces 32 are inserted in engaging holes 33 made in the printed wiring board 14, and fixed to the printed wiring board 14 by such a means as reflow soldering.

As a result of this fixing, the connector main body 21 is held by the printed wiring board 14 in such a manner as to pass through the connector mounting portion 20 in the thickness direction of the printed wiring board 14. When the connector main body 21 is held by the printed wiring board 14, the end face 26 of the insulating block 23 is located inside the opening 8 of the first housing 4. In the meantime, a gap G into which to put the plug 10 is formed between the cover 24 and the opening 8.

As shown in FIG. 2 and FIG. 3, a first mark 35 and a second mark 36 are provided in the connector main body 21 of the RGB connector 16. The first mark 35 and the second mark 36 are elements used to visually examine the degree of the tilt of the connector main body 21 relative to the mounting surface 17.

More specifically, as shown in FIG. 3, the first mark 35 is provided on one side surface 27a of the cover 24 that constitutes the connector main body 21. The first mark 35 comprises three standard lines 35a, 35b, and 35c. Standard lines 35a, 35b, and 35c linearly extend in a direction along the mounting surface 17 of the printed wiring board 14, and are arranged parallel to one another to keep a given distance C1 in the thickness direction of the printed wiring board 14. The distance C1 between standard lines 35a, 35b, and 35c is, for example, 0.1 mm.

According to the first embodiment, in order to clearly indicate the first mark 35, three linear grooves that shape standard lines 35a, 35b, and 35c are formed in one side surface 27a of the cover 24, and the inner surfaces of the grooves are painted in a color opposite to the color of side surface 27a. For example, when side surface 27a is silver-colored, standard lines 35a, 35b, and 35c can be indicated in blue.

The second mark 36 is provided at the end of the end face 26 of the insulating block 23 that constitutes the connector main body 21. The second mark 36 comprises three standard lines 36a, 36b, and 36c. Standard lines 36a, 36b, and 36c linearly extend in a direction along the mounting surface 17 of the printed wiring board 14, and are arranged parallel to one another to keep a given distance C2 in the thickness direction of the printed wiring board 14. The distance C2 between standard lines 36a, 36b, and 36c is, for example, 0.1 mm.

According to the first embodiment, in order to clearly indicate the second mark 36, three linear grooves that shape standard lines 36a, 36b, and 36c are formed in the end face 26 of the insulating block 23, and the inner surfaces of the grooves are painted in a color opposite to the color of the end face 26. For example, when the end face 26 is black, standard lines 36a, 36b, and 36c can be indicated in white.

According to the first embodiment, the RGB connector 16 is reflow-soldered to the printed wiring board 14 while the connector main body 21 is pushed in the connector mounting portion 20 of the printed wiring board 14. The connector mounting portion 20 is defined by a void cutout that opens in the side edge 18 of the printed wiring board 14.

Accordingly, the connector main body 21 passes through the connector mounting portion 20 in the thickness direction of the printed wiring board 14. Therefore, the printed wiring board 14 cannot directly support the connector main body 21. Moreover, as the connector holder 22 that supports the connector main body 21 is located off the center of gravity of the RGB connector 16, the center of gravity of the RGB connector 16 is badly-balanced.

As a result, when the RGB connector 16 is soldered to the printed wiring board 14, the RGB connector 16 may tilt relative to the mounting surface 17 in such a manner as to shake its head in the thickness direction of the printed wiring board 14.

FIG. 2 and FIG. 3 show how the RGB connector 16 is soldered to the mounting surface 17 of the printed wiring board 14 without being tilted relative to the mounting surface 17. In this condition, standard lines 35a, 35b, and 35c that define the first mark 35 and standard lines 36a, 36b, and 36c that define the second mark 36 are parallel to the mounting surface 17 of the printed wiring board 14. At the same time, the second standard lines 35b and 36b are kept in such a positional relationship as to overlap the mounting surface 17 when the RGB connector 16 is viewed from the direction of the end face 26 and from the direction of side surface 27a.

Thus, an operator observes the parallelisms of the first and second mark 35 and 36 relative to the mounting surface 17 and their positional relationship, and can thereby visually recognize that the RGB connector 16 is soldered to the mounting surface 17 without being tilted relative to the mounting surface 17.

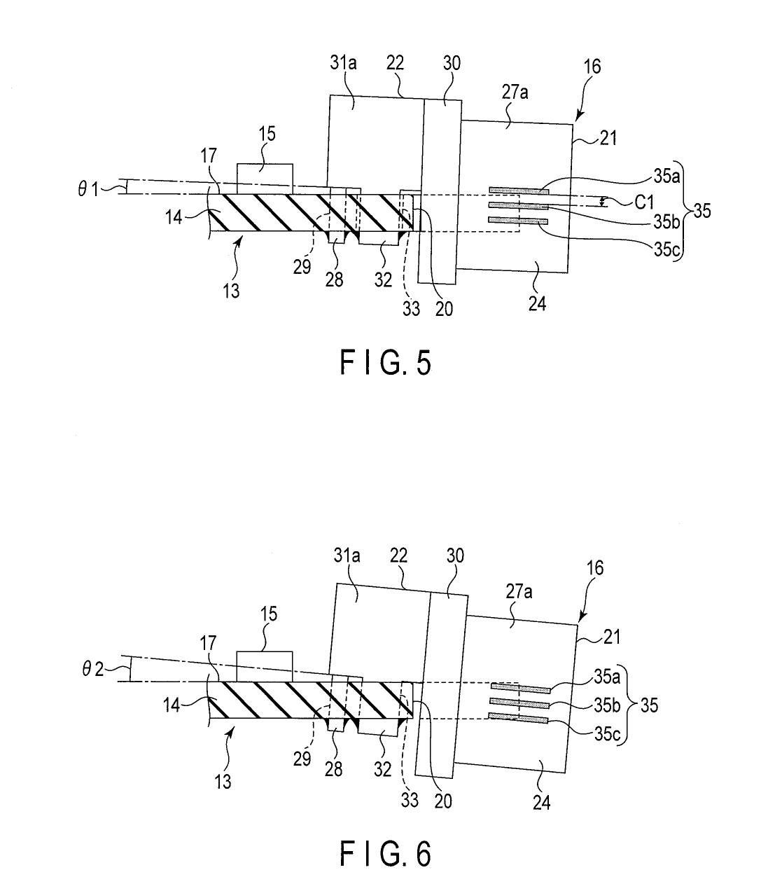

FIG. 5 shows a condition in which the RGB connector 16 is tilted downward relative to the mounting surface 17 of the printed wiring board 14 at an angle θ1. In this condition, the parallelisms of standard lines 35a, 35b, and 35c relative to the mounting surface 17 are lost, and the mounting surface 17 is located between the upper standard line 35a and the middle standard line 35b.

As a result, it is possible to visually recognize that the RGB connector 16 is tilted about 0.1 mm relative to the mounting surface 17. It is also possible to determine that the degree of the tilt of the RGB connector 16 is within an allowable range if the tilt of the RGB connector 16 relative to the mounting surface 17 is about 0.1 mm.

Meanwhile, FIG. 6 shows a condition in which the RGB connector 16 is tilted downward relative to the mounting surface 17 of the printed wiring board 14 at an angle θ2. The angle θ2 is greater than the angle θ1. In this condition, the parallelisms of standard lines 35a, 35b, and 35c relative to the mounting surface 17 are lost, and the mounting surface 17 is upwardly beyond the upper standard line 35a.

As a result, the degree of the tilt of the RGB connector 16 relative to the mounting surface 17 is outside the allowable range, and it can be determined that the RGB connector 16 is improperly mounted.

According to the first embodiment, the operator observes the parallelisms of the first mark 35 and the second mark 36 relative to the mounting surface 17 and their positional relationship, and can thereby visually determine whether the degree of the tilt of the RGB connector 16 is within the allowable range. Thus, as compared with a conventional examination technique that uses a thickness gauge, the degree of the tilt of the RGB connector 16 can be easily examined in a short time.

Moreover, as the degree of the tilt of the RGB connector 16 can be examined without using the thickness gauge, it is not necessary to secure a space to insert the thickness gauge around the connector mounting portion 20. In other words, the circuit components 15 can be disposed on the mounting surface 17 of the printed wiring board 14 to surround the RGB connector 16. Therefore, the circuit components 15 can be highly densely mounted on the mounting surface 17, and unnecessary spaces on the mounting surface 17 can be eliminated.

Although the first mark 35 and the second mark 36 are provided in the connector main body 21 according to the first embodiment, any one of the marks may be omitted.

Furthermore, the marks are not exclusively configured so that the inner surfaces of the grooves are painted. The inner surfaces do not have to be painted. Instead of providing the grooves, a seal in which a plurality of standard lines are printed may be attached to the connector main body.

In addition, the connector mounting portion is not particularly the cutout that opens in the side edge of the printed wiring board. For example, the connector mounting portion may comprise a void region defined by a hole passing through the printed wiring board in its thickness direction.

### Second Embodiment

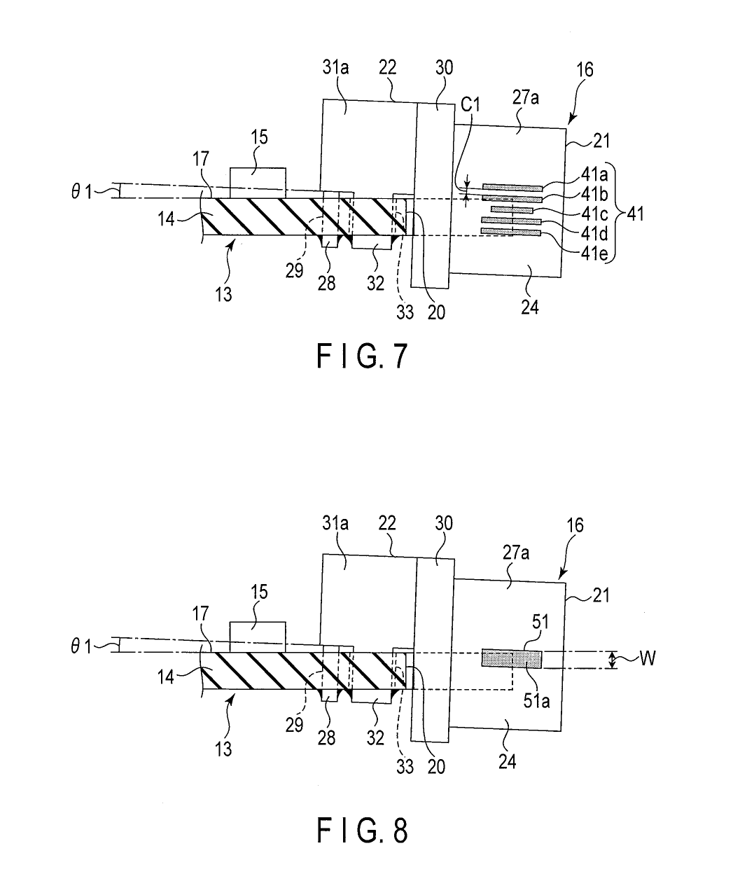

FIG. 7 discloses the second embodiment.

The second embodiment is different from the first embodiment in the configuration of the first mark. The configuration of a circuit module is similar in other respects to that according to the first embodiment. Therefore, in the second embodiment, the same components are those according to the first embodiment are provided with the same reference signs and are not described.

As shown in FIG. 7, a first mark 41 provided on a side surface 27a of a connector main body 21 comprises five standard lines 41a, 41b, 41c, 41d, and 41e. Standard lines 41a, 41b, 41c, 41d, and 41e linearly extend in a direction along a mounting surface 17 of a printed wiring board 14, and are arranged parallel to one another to keep a given distance in the thickness direction of the printed wiring board 14. The distance C1 between standard lines 41a, 41b, 41c, 41d, and 41e is, for example, 0.1 mm.

According to the second embodiment, the third middle standard line 41c is smaller in length than the adjacent second standard line 41b and fourth standard line 41d. Moreover, the third standard line 41c is provided to be parallel to the mounting surface 17 and to exactly overlap the mounting surface 17, for example, when an RGB connector 16 is soldered to the mounting surface 17 without being tilted relative to the mounting surface 17.

According to the second embodiment, in order to clearly indicate the first mark 41, five linear grooves that shape standard lines 41a, 41b, 41c, 41d, and 41e are formed in one side surface 27a of a cover 24, and the inner surfaces of the grooves are painted in a color opposite to the color of side surface 27a. For example, when side surface 27a is silver-colored, standard lines 41a, 41b, 41c, 41d, and 41e can be indicated in green.

According to the second embodiment, by observing the parallelisms of the mounting surface 17 of the printed wiring board 14 and the middle standard line 41c and their positional relationship, it is possible to visually determine whether the degree of the tilt of the RGB connector 16 is within an allowable range. That is, for example, if the mounting surface 17 extends along the middle standard line 41c or if the mounting surface 17 is between standard line 41c and standard line 41b or between standard line 41c and standard line 41d, it can be determined that the degree of the tilt of the RGB connector 16 relative to the mounting surface 17 is within the allowable range. Otherwise, it can be determined that the degree of the tilt of the RGB connector 16 is outside the allowable range. Thus, as in the first embodiment, the degree of the tilt of the RGB connector 16 can be easily examined in a short time.

### Third Embodiment

FIG. 8 discloses the third embodiment.

The third embodiment is different from the first embodiment in the configuration of the first mark. The configuration of a circuit module is similar in other respects to that according to the first embodiment. Therefore, in the third embodiment, the same components are those according to the first embodiment are provided with the same reference signs and are not described.

As shown in FIG. 8, a first mark 51 provided on a side surface 27a of a connector main body 21 comprises one standard line 51a. Standard line 51a linearly extends in a direction along a mounting surface 17 of a printed wiring board 14, and has a constant width dimension W along the thickness direction of the printed wiring board 14.

According to the third embodiment, in order to clearly indicate the first mark 51, one linear groove that shapes standard line 51a is formed in one side surface 27a of a cover 24, and the inner surface of the groove is painted in a color opposite to the color of side surface 27a. For example, when side surface 27a is silver-colored, standard line 51a can be indicated in red.

According to the third embodiment, by observing the positional relationship between the mounting surface 17 of the printed wiring board 14 and standard line 51a, it is possible to visually determine whether the degree of the tilt of the RGB connector 16 relative to the mounting surface 17 is within an allowable range.

That is, if the mounting surface 17 is within the width dimension W of the first mark 51, it can be determined that the degree of the tilt of the RGB connector 16 is within the allowable range. Otherwise, it can be determined that the degree of the tilt of the RGB connector 16 is outside the allowable range. Thus, as in the first embodiment, the degree of the tilt of the RGB connector 16 can be easily examined in a short time.

Although the RGB connector is described as an example of a connector in the first to third embodiments, the connector to be mounted on the printed wiring board is not limited to the RGB connector. For example, a USB connector or an HDMI connector is also applicable.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A connector on a substrate, the connector comprising:
a connector main body on a connector mounting portion of the substrate, the connector main body comprising an outer surface; and
a mark on the outer surface of the connector main body, the mark indicating a positional relationship between the connector main body and the substrate.

2. The connector of claim 1, wherein the mark extends in a direction along a mounting surface of the substrate.

3. The connector of claim 2, wherein the mark comprises a plurality of standard lines, the standard lines extending in a direction along the mounting surface and positioned parallel relative to each other and perpendicular to a thickness direction of the substrate.

4. The connector of claim 3, wherein the standard lines positioned adjacent to each other are different in length.

5. The connector of claim 1, wherein the outer surface of the connector main body comprises an end face having an open hole configured to accept a plug, and a side surface facing in a direction different from the end face, and wherein the mark is on at least one of the end face and the side surface.

6. The connector of claim 2, further comprising a support member configured to support the connector main body, the support member connected to the mounting surface of the substrate.

7. A circuit module comprising:
a wiring board comprising a connector mounting portion; and
a connector on the connector mounting portion of the wiring board, the connector comprising an outer surface, and a mark on the outer surface, the mark indicating a positional relationship between the connector and the wiring board.

8. The circuit module of claim 7, wherein the mark extends in a direction along a mounting surface of the wiring board.

9. The circuit module of claim 8, wherein the mark comprises a plurality of standard lines, the standard lines extending in a direction along the mounting surface and positioned parallel apart relative to each other and perpendicular to a thickness direction of the wiring board.

10. The circuit module of claim 9, wherein the outer surface of the connector comprises an end face having an open hole configured to accept a plug, and a side surface facing in a direction different from the end face, and wherein the mark is on at least one of the end face and the side surface.

11. The circuit module of claim 8, wherein the connector mounting portion is defined by a region passing through the wiring board in a thickness direction of the wiring board, and wherein the connector comprises a connector main body in the connector mounting portion, the connector main body comprising a support member, the support member connected to the mounting surface of the wiring board.

12. The circuit module of claim 11, further comprising circuit components on the mounting surface positioned around the connector.

13. An electronic apparatus comprising:
a housing comprising an opening;
a wiring board in the housing, the wiring board comprising a connector mounting portion; and
a connector on the connector mounting portion of the wiring board, the connector facing the opening, the connector comprising an outer surface, and a mark on the outer surface, the mark indicating a positional relationship between the connector and the wiring board.

14. The electronic apparatus of claim 13, wherein the connector mounting portion comprises a region passing through the wiring board in a thickness direction of the wiring board, the region facing the opening of the housing, wherein the connector comprises a connector main body in the connector mounting portion and a support member in the connector main body, the support member connected to a mounting surface of the wiring board, and wherein the mark is in the connector main body.

15. The connector of claim 1, wherein the positional relationship between the connector main body and the substrate comprises a degree of tilt of the connector main body relative to a mounting surface of the substrate.

16. The circuit module of claim 7, wherein the positional relationship between the connector and the wiring board comprises a degree of tilt of the connector relative to a mounting surface of the wiring board.

17. The electronic apparatus of claim 13, wherein the positional relationship between the connector and the wiring board comprises a degree of tilt of the connector relative to a mounting surface of the wiring board.
